(19) United States
(12) Patent Application Publication
(10) Pub. No.: US 2024/0072763 A1
(43) Pub. Date: Feb. 29, 2024

(54) ACOUSTIC WAVE DEVICE AND METHOD OF MANUFACTURING ACOUSTIC WAVE DEVICE

(71) Applicant: Murata Manufacturing Co., Ltd., Nagaokakyo-shi (JP)

(72) Inventor: Kenta MAEDA, Nagaokakyo-shi (JP)

(21) Appl. No.: 18/229,209

(22) Filed: Aug. 2, 2023

(30) Foreign Application Priority Data
Aug. 23, 2022 (JP) 2022-132773

(51) Int. Cl. H03H 9/13; H03H 3/02; H03H 9/17; H03H 9/54

(52) U.S. Cl. CPC H03H 9/133; H03H 3/02; H03H 9/176; H03H 9/54

(57) ABSTRACT

An acoustic wave device includes a piezoelectric substrate, and a longitudinally coupled resonator on a main surface of the piezoelectric substrate and including an even number of four or more IDT electrodes. Of the even number of IDT electrodes, in a pair of outermost IDT electrodes, a number of electrode fingers of one IDT electrode is two.

### CROSS REFERENCE TO RELATED APPLICATIONS

This application claims the benefit of priority to Japanese Patent Application No. 2022-132773 filed on Aug. 23, 2022. The entire contents of this application are hereby incorporated herein by reference.

### BACKGROUND OF THE INVENTION

### 1. Field of the Invention

The present disclosure relates to an acoustic wave device and a method of manufacturing the acoustic wave device.

### 2. Description of the Related Art

As communication technology advances, the importance of mobile communications networks capable of performing high-capacity data communications at higher speeds is increasing. Furthermore, mobile terminals used in the mobile communications networks are preferably able to support many bands at higher radio frequencies. An acoustic wave filter has characteristics suitable for such a mobile terminal, and the importance of the acoustic wave filter is also increasing.

In an acoustic wave device, such as an acoustic wave filter, used in mobile terminals, the steepness of a boundary between a pass band and a stop band and high attenuation in the stop band are necessary. Japanese Unexamined Patent Application Publication No. 2021-190908 discloses a band elimination filter that facilitates making an attenuation slope at a boundary between a pass band and a stop band steeper.

### SUMMARY OF THE INVENTION

Preferred embodiments of the present invention provide acoustic wave devices that each have excellent attenuation characteristics outside a band and methods of manufacturing such acoustic wave devices.

An acoustic wave device according to a preferred embodiment of the present invention includes a piezoelectric substrate, and a longitudinally coupled resonator on a main surface of the piezoelectric substrate and including an even number of four or more interdigital transducer (IDT) electrodes. Of the even number of IDT electrodes, a number of electrode fingers of one of a pair of outermost IDT electrodes is two.

In preferred embodiments of the present invention, acoustic wave devices that each have excellent attenuation characteristics outside a band, and methods of manufacturing the acoustic wave devices are provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view illustrating an example of the structure of an acoustic wave device according to a first preferred embodiment of the present invention.

FIG. 2 is a schematic plan view illustrating the structure of an IDT electrode of the acoustic wave device illustrated in FIG. 1.

FIG. 3 is a schematic plan view illustrating the structure of an IDT electrode of the acoustic wave device illustrated in FIG. 1.

FIG. 4 is a schematic plan view illustrating the structure of a reflector of the acoustic wave device illustrated in FIG. 1.

FIG. 5 is a flowchart illustrating an example of a method of manufacturing the acoustic wave device according to the first preferred embodiment of the present invention.

FIG. 6 is a circuit diagram illustrating an example of the structure of an acoustic wave device according to a second preferred embodiment of the present invention.

FIG. 7 is a circuit diagram illustrating another example of the structure of an acoustic wave device according to the second preferred embodiment of the present invention.

FIG. 8 is a schematic plan view illustrating the structure of an acoustic wave device in Reference Example 1.

FIG. 9 is a schematic plan view illustrating the structure of an acoustic wave device in Reference Example 2.

FIG. 10 is a graph illustrating an example of attenuation characteristics of filters in Practical Example and Reference Examples obtained by simulation.

FIG. 11 is a graph illustrating an example of attenuation characteristics of the filters in Practical Example and Reference Examples obtained by simulation.

FIG. 12 is a diagram illustrating an example of in-band impedance characteristics of the filters in Practical Example and Reference Examples obtained by simulation.

FIG. 13 is a diagram illustrating an example of in-band impedance characteristics of the filters in Practical Example and Reference Examples obtained by simulation.

FIG. 14 is a graph illustrating an example of attenuation characteristics of filters in Reference Examples obtained by simulation.

FIG. 15 is a graph illustrating an example of attenuation characteristics of the filters in Reference Examples obtained by simulation.

### DETAILED DESCRIPTION OF THE PREFERRED EMBODIMENTS

When a band pass filter including a longitudinally coupled resonator is designed, the location of an attenuation pole located outside a pass band and attenuation need to be adjusted. These adjustments are typically made by changing, for example, the capacitance of an IDT electrode and a wavelength determined by a distance between electrode fingers. When the location of an attenuation pole and attenuation are adjusted, however, characteristics in the pass band of the filter also vary. That is, it is difficult to design characteristics in the pass band and characteristics outside the pass band independently of each other.

In view of such an issue, the inventor of preferred embodiments of the present invention has conceived of acoustic wave devices in each of which characteristics outside a pass band can be adjusted while reducing variations in characteristics in the pass band, and methods of manufacturing the acoustic wave devices.

Preferred embodiments of the present invention will be described below with reference to the drawings. The present invention is not limited to the following preferred embodiments, and appropriate design changes can be made within a range in which configurations of the present invention are satisfied. Furthermore, in the following description, common reference numerals are used in different drawings to denote the same or corresponding portions or portions with similar functions, and a repetitive description of the portions is omitted in some cases. Furthermore, configurations described in preferred embodiments and modifications may be appropriately combined or may be changed without departing from the gist of the present invention. To provide an easy-to-understand explanation, in drawings that are referred to below, in some cases, a simplified or schematic configuration is illustrated, or some components are omitted. In particular, the number of illustrated electrode fingers of an IDT electrode is sometimes smaller than the actual number of electrode fingers for the sake of clarity. Furthermore, a dimensional ratio between components illustrated in each drawing is not necessarily an actual dimensional ratio.

### First Preferred Embodiment

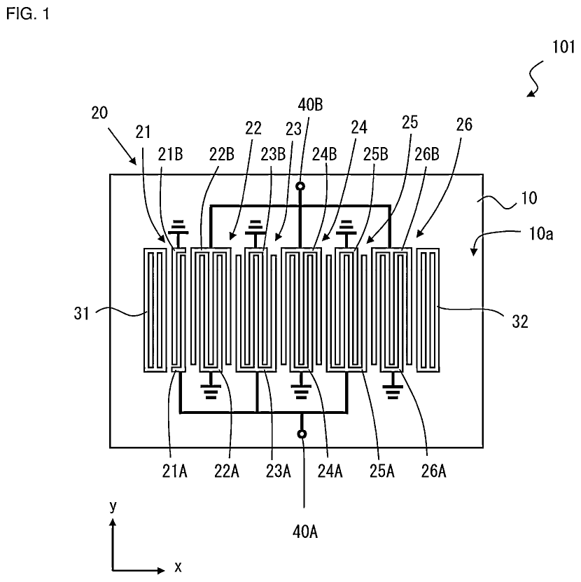

FIG. 1 is a schematic plan view illustrating the structure of an acoustic wave device 101 according to a first preferred embodiment of the present invention. The acoustic wave device 101 according to the present preferred embodiment is an acoustic wave device used, for example, in a band from about 700 MHz to about 2500 MHz and is used, for example, as a filter, particularly using, for example, surface acoustic wave. The acoustic wave device 101 includes a piezoelectric substrate 10 and a longitudinally coupled resonator 20. The acoustic wave device 101 may further include reflectors 31 and 32.

The piezoelectric substrate 10 includes a main surface 10a and has piezoelectricity. The piezoelectric substrate 10 is made of a piezoelectric single crystal, such as, for example, LiTaO₃ or LiNbO₃. The piezoelectric substrate 10 may be made of piezoelectric ceramics. Furthermore, the piezoelectric substrate 10 may be a laminated structure in which a piezoelectric thin film is disposed on a supporting substrate or may be, for example, a laminated structure in which one or more dielectric films are further disposed between the supporting substrate and the piezoelectric thin film. In the present preferred embodiment, the piezoelectric substrate 10 is, for example, a rotated Y cut LiTaO₃ substrate, and a rotation angle is preferably in a range of not less than about 116° and not more than about 136°.

The longitudinally coupled resonator 20 is located on the main surface 10a of the piezoelectric substrate 10. The longitudinally coupled resonator 20 includes an even number of four or more interdigital transducer (IDT) electrodes. In the present preferred embodiment, the longitudinally coupled resonator 20 includes, for example, six IDT electrodes. Specifically, the longitudinally coupled resonator 20 includes an IDT electrode 21, an IDT electrode 22, an IDT electrode 23, an IDT electrode 24, an IDT electrode 25, and an IDT electrode 26. The IDT electrode 21 and the IDT electrode 26 refer to a pair of outermost IDT electrodes in the longitudinally coupled resonator 20. Each IDT electrode includes a pair of comb-shaped electrodes including electrode fingers interdigitated with each other.

The IDT electrode 21 includes a first comb-shaped electrode 21A and a second comb-shaped electrode 21B. Similarly, the IDT electrode 22 includes a first comb-shaped electrode 22A and a second comb-shaped electrode 22B. The IDT electrode 23 includes a first comb-shaped electrode 23A and a second comb-shaped electrode 23B. The IDT electrode 24 includes a first comb-shaped electrode 24A and a second comb-shaped electrode 24B. Furthermore, the IDT electrode 25 includes a first comb-shaped electrode 25A and a second comb-shaped electrode 25B, and the IDT electrode 26 includes a first comb-shaped electrode 26A and a second comb-shaped electrode 26B.

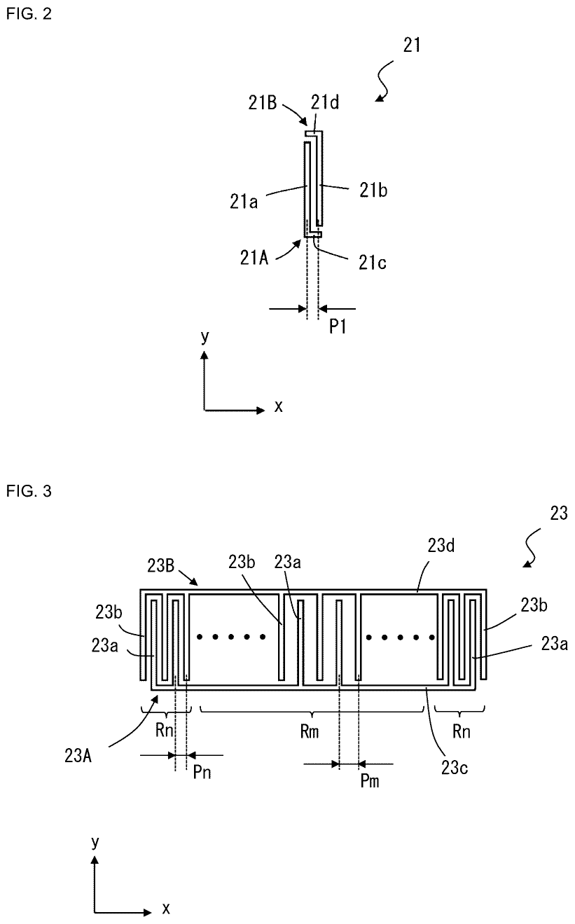

FIG. 2 is a schematic plan view illustrating the structure of the IDT electrode 21 in an enlarged manner. The IDT electrode 21 includes two electrode fingers. Specifically, the first comb-shaped electrode 21A includes a first electrode finger 21a, and a first busbar 21c connected to one end of the first electrode finger 21a. The second comb-shaped electrode 21B includes a second electrode finger 21b, and a second busbar 21d connected to one end of the second electrode finger 21b. The IDT electrode 21 does not have to include the first busbar 21c and the second busbar 21d.

A pitch P1 of two electrode fingers of the IDT electrode 21 is defined as a center-to-center distance between a pair of electrode fingers adjacent to each other in a direction (x-axis direction) perpendicular or substantially perpendicular to a direction in which the electrode fingers extend.

On the other hand, each of the IDT electrodes 22, 23, 24, 25, and 26 includes, for example, three or more electrode fingers. The number of electrode fingers that can be provided is any number. For example, the number of electrode fingers is not less than 3 and not more than 50, preferably not less than 20 and not more than 40. FIG. 3 is a schematic plan view illustrating the structure of the IDT electrode 23 in an enlarged manner. In the IDT electrode 23, the first comb-shaped electrode 23A includes a plurality of first electrode fingers 23a, and a first busbar 23c connected to one ends of the plurality of first electrode fingers 23a. The second comb-shaped electrode 23B includes a plurality of second electrode fingers 23b, and a second busbar 23d connected to one ends of the second electrode fingers 23b. In the entire IDT electrode 23, all pitches of electrode fingers may be the same or substantially the same, or there may be regions that are different in electrode finger pitch.

In the present preferred embodiment, the IDT electrode 23 includes a main region Rm located in the center, and a pair of narrow pitch regions Rn between which the main region Rm is interposed. In each of the main region Rm and the narrow pitch regions Rn, pitches of electrode fingers may be the same or substantially the same in the region, or some or all of the pitches may be different.

An average pitch of electrode fingers in each narrow pitch region Rn is smaller than an average pitch of electrode fingers in the main region Rm. More specifically, when an average pitch of electrode fingers in the narrow pitch region Rn is Pn and an average pitch of electrode fingers in the main region Rm is Pm, it is preferable, for example, that Pn and Pm satisfy a relationship of Pn about 0.95×Pm. Here, each of the average pitches of electrode fingers in the narrow pitch region Rn and the main region Rm can be obtained by dividing a center-to-center distance in the x-axis direction between electrode fingers located at both ends of each region by the number of gaps in the region (the number of electrode fingers in the region−1).

The IDT electrodes 22, 24, 25, and 26 also have a structure the same as or similar to that of the IDT electrode 23. The IDT electrodes 22, 23, 24, 25, and 26 may be the same or different in the number of electrode fingers and electrode finger pitch.

Furthermore, in the present preferred embodiment, the IDT electrodes 23 to 25 include, as described with reference to FIG. 3, the main region Rm, and the pair of narrow pitch regions Rn located on both sides in the x-axis direction with respect to the main region Rm. On the other hand, the IDT electrode 22 includes a main region Rm, and a narrow pitch region Rn located on an IDT electrode 23 side with respect to the main region Rm. Furthermore, the IDT electrode 26 includes a main region Rm, and a narrow pitch region Rn located on an IDT electrode 25 side with respect to the main region Rm. That is, the IDT electrode 22 includes no narrow pitch region on an IDT electrode 21 side, and the IDT electrode 26 includes no narrow pitch region on a reflector 32 side. However, the IDT electrode 22 may include a narrow pitch region on the IDT electrode 21 side. In other words, in the IDT electrodes 22, 23, 24, 25, and 26, the narrow pitch region Rn may be provided in a region where IDT electrodes are adjacent to each other.

As illustrated in FIG. 1, the IDT electrodes 21, 22, 23, 24, 25, and 26 are arranged, on the main surface 10a of the piezoelectric substrate 10, in a direction orthogonal or substantially orthogonal to a direction in which their electrode fingers extend. In FIG. 1, the electrode fingers of the IDT electrodes 21, 22, 23, 24, 25, and 26 extend in parallel to a y axis, and the IDT electrodes 21, 22, 23, 24, 25, and 26 are arranged in the x-axis direction. An acoustic wave excited in the piezoelectric substrate 10 by the longitudinally coupled resonator 20 propagates in the x-axis direction perpendicular to the y axis.

The first comb-shaped electrode 21A of the IDT electrode 21, the first comb-shaped electrode 23A of the IDT electrode 23, and the first comb-shaped electrode 25A of the IDT electrode 25 are electrically connected to one another and are connected to an input-output terminal 40A. On the other hand, the second comb-shaped electrode 21B of the IDT electrode 21, the second comb-shaped electrode 23B of the IDT electrode 23, and the second comb-shaped electrode 25B of the IDT electrode 25 are each connected to a reference potential.

Furthermore, the second comb-shaped electrode 22B of the IDT electrode 22, the second comb-shaped electrode 24B of the IDT electrode 24, and the second comb-shaped electrode 26B of the IDT electrode 26 are electrically connected to one another and are connected to an input-output terminal 40B. The first comb-shaped electrode 22A of the IDT electrode 22, the first comb-shaped electrode 24A of the IDT electrode 24, and the first comb-shaped electrode 26A of the IDT electrode 26 are each connected to the reference potential.

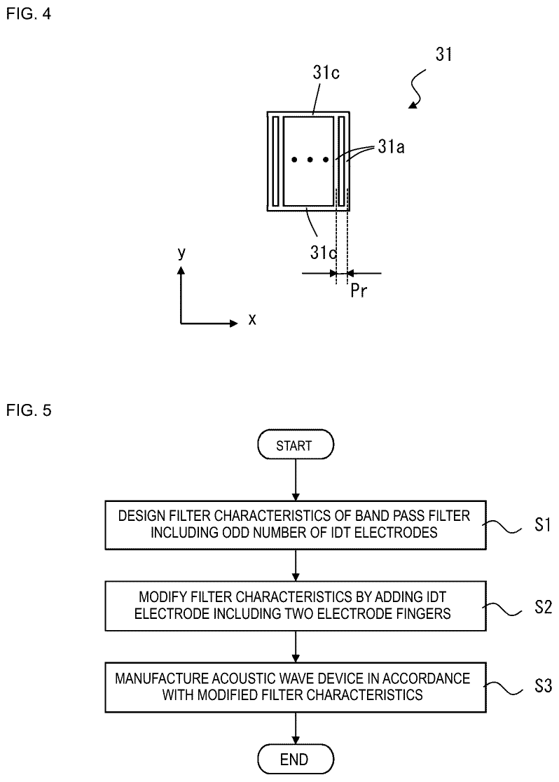

The longitudinally coupled resonator 20 may further include a reflector. In the present preferred embodiment, the longitudinally coupled resonator 20 includes a pair of reflectors 31 and 32 on outer sides in the x-axis direction of the IDT electrodes 21 to 26. FIG. 4 is a schematic plan view illustrating the structure of the reflector 31 in an enlarged manner. The reflector 31 includes a plurality of electrode fingers 31a. Both ends of each electrode finger 31a are connected to respective busbars 31c. The reflector 32 also has a structure the same as or similar to that of the reflector 31. The reflectors 31 and 32 may be the same or different in the number of electrode fingers and electrode finger pitch.

The IDT electrodes 23, 24 25, and 26, and the reflectors 31 and 32 are made of a single metal layer or multiple metal layers. A metal layer is made of, for example, one metal selected from the group consisting of Al, Pt, Au, Cu, W, Mo, Ta, Ni, and Cr, or an alloy including at least one metal selected from the group consisting of Al, Pt, Au, Cu, W, Mo, Ta, Ni, and Cr.

In the acoustic wave device 101, of an even number of four or more IDT electrodes in the longitudinally coupled resonator 20, the IDT electrode 21 including two electrode fingers is located on an outermost side in the x-axis direction, thus enabling an improvement in attenuation characteristics at an attenuation pole located outside a band of a band pass filter formed by the other IDT electrodes 22, 23, 24, 25, and 26. For example, attenuation at a frequency location closer to a high frequency side of a pass band can be increased. Thus, on the high frequency side of the pass band, a boundary between the pass band and a stop band can be made steeper. On the other hand, in the pass band, good bandpass characteristics can be provided.

As described in detail below, it is preferable that an IDT electrode including two electrode fingers is disposed, of both ends in an acoustic wave propagation direction of a longitudinally coupled resonator, only at one end. If IDT electrodes including two electrode fingers are disposed at both ends in the acoustic wave propagation direction, attenuation characteristics on a high frequency side of a pass band are improved, but attenuation characteristics near the pass band sometimes deteriorate. Furthermore, in-band impedance characteristics sometimes change.

Furthermore, when an average value of main pitches Pm of the respective IDT electrodes 22, 23, 24, 25, and 26 other than the IDT electrode 21 is P2, it is preferable that a relationship between P2 and the pitch P1 of electrode fingers of the IDT electrode 21 satisfy the following relational expression (1).

0.97×P2≤P1≤2.1×P2 (1)

When P1 and P2 satisfy the expression (1), good passband characteristics can be obtained with, for example, no ripple occurring in the pass band.

Next, a non-limiting example of a method of manufacturing the acoustic wave device 101 according to the present preferred embodiment will be described. FIG. 5 is a flowchart illustrating a method of manufacturing the acoustic wave device 101 according to the present preferred embodiment.

In many cases, a typical longitudinally coupled resonator includes an odd number of IDT electrodes. This is because it is not easy to appropriately adjust the phase of an acoustic wave that propagates if an even number of IDT electrodes are included.

Although the acoustic wave device 101 according to the present preferred embodiment includes the longitudinally coupled resonator including an even number of IDT electrodes, filter characteristics of the longitudinally coupled resonator including the even number of IDT electrodes are designed in accordance with the design of a typical longitudinally coupled resonator including an odd number of IDT electrodes.

A non-limiting example of a method of manufacturing an acoustic wave device according to the present preferred embodiment includes a first step (S1) of designing filter characteristics of a band pass filter including an odd number of IDT electrodes, a second step (S2) of modifying the filter characteristics obtained in the first step, and a third step (S3) of manufacturing an acoustic wave device in accordance with the modified filter characteristics. Each step will be described in detail below.

### 1. First Step (S1)

First, filter characteristics of a band pass filter including a longitudinally coupled resonator including an odd number of three or more IDT electrodes are designed. The band pass filter including the longitudinally coupled resonator including an odd number of IDT electrodes can be designed by using a method similar to an existing method.

### 2. Second Step (S2)

Next, the filter characteristics are modified by adding an IDT electrode including two electrode fingers at one end of the odd number of IDT electrodes. When the IDT electrode including the two electrode fingers is added, a capacitance component of this IDT electrode is added to the band pass filter that is designed, and the location (frequency) of an attenuation pole can be changed. The magnitude of capacitance can be adjusted by a pitch of the two electrode fingers. When the attenuation pole is provided at an appropriate location, a boundary between a pass band and a stop band can be made steeper, that is, the sharpness of the filter characteristics can be improved. Furthermore, when the number of electrode fingers of the IDT that is added is two, the influence on basic band characteristics of the band pass filter designed in the first step is reduced, and in-band characteristics can be maintained.

After the IDT electrode including the two electrode fingers is added, the band pass filter designed in the first step may be adjusted by changing, for example, a pitch of electrode fingers and the number of electrode fingers of an IDT electrode in the longitudinally coupled resonator including the odd number of IDT electrodes.

### 3. Third Step (S3)

In accordance with the modified filter characteristics, a longitudinally coupled resonator is formed on a piezoelectric substrate, and an acoustic wave device is manufactured. Specifically, the pattern of IDT electrodes and reflectors is determined by using parameters used in the modified filter characteristics, or more specifically, the number of electrode fingers, a pitch of electrode fingers, and others, and a photomask for forming IDT electrodes and others is fabricated by using the determined pattern. An acoustic wave device is manufactured by using the fabricated photomask in accordance with typical manufacturing technology and manufacturing process of an acoustic wave device.

In the method of manufacturing an acoustic wave device according to the present preferred embodiment, first, filter characteristics of a band pass filter including a longitudinally coupled resonator including an odd number of three or more IDT electrodes are designed. The filter characteristics are modified by adding an IDT electrode including two electrode fingers to the filter having the filter characteristics. At this time, the location of an attenuation pole located outside a pass band is mainly affected, and a change in characteristics in the pass band is small. Thus, the filter characteristics can be modified without the design of the entire filter being adjusted, and an acoustic wave device according to the present preferred embodiment can be designed even without a longitudinally coupled resonator including an even number of IDT electrodes that is not easy to design being used.

### Second Preferred Embodiment

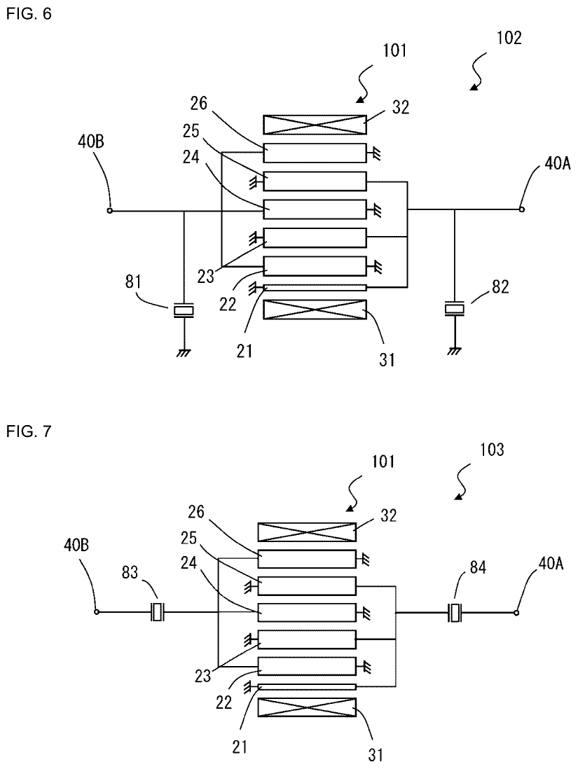

FIG. 6 is a circuit diagram illustrating the structure of an acoustic wave device 102 according to a second preferred embodiment of the present invention. The acoustic wave device 102 differs from the acoustic wave device 101 according to the first preferred embodiment in that at least one parallel resonator is included in addition to the longitudinally coupled resonator 20. The at least one resonator is connected between a path connecting the acoustic wave device 101 including the longitudinally coupled resonator 20 and one of the input-output terminals 40A and 40B and the reference potential.

As illustrated in FIG. 6, in the present preferred embodiment, the acoustic wave device 102 includes the longitudinally coupled resonator 20 according to the first preferred embodiment, a first parallel resonator 81, and a second parallel resonator 82. In the acoustic wave device 102, the first parallel resonator 81 and the second parallel resonator 82 are each connected in parallel with the longitudinally coupled resonator 20.

More specifically, the first parallel resonator 81 is connected between the input-output terminal 40B and the reference potential, and the second parallel resonator 82 is connected between the input-output terminal 40A and the reference potential. The reference potential is a potential defining and functioning as a basis for operating the acoustic wave device and is usually 0 V. However, the reference potential is not limited to 0 V and may be a potential of another value. The first parallel resonator 81 and the second parallel resonator 82 are disposed for attenuation level adjustment and impedance adjustment in the band pass filter implemented by the longitudinally coupled resonator 20. In the acoustic wave device 102, one of the first parallel resonator 81 and the second parallel resonator 82 does not have to be provided.

Even when the acoustic wave device 102 includes the first parallel resonator 81 and the second parallel resonator 82, advantageous effects the same as or similar to those achieved by the acoustic wave device 101 according to the first preferred embodiment can be obtained. That is, the IDT electrode 21 can produce the advantageous effect of improving attenuation characteristics at an attenuation pole located outside the band of the band pass filter while maintaining in-band characteristics.

An acoustic wave device according to the present preferred embodiment may include at least one series resonator in addition to the longitudinally coupled resonator 20. The at least one series resonator is connected in series with a path connecting the acoustic wave device 101 including the longitudinally coupled resonator 20 and one of the input-output terminals 40A and 40B. As illustrated in FIG. 7, an acoustic wave device 103 includes the longitudinally coupled resonator 20 according to the first preferred embodiment, a first series resonator 83, and a second series resonator 84. In the acoustic wave device 103, the first series resonator 83 and the second series resonator 84 are each connected in series with the longitudinally coupled resonator 20.

More specifically, the first series resonator 83 is connected between the input-output terminal 40B and the longitudinally coupled resonator 20, and the second series resonator 84 is connected between the longitudinally coupled resonator 20 and the input-output terminal 40A. In the acoustic wave device 103, one of the first series resonator 83 and the second series resonator 84 does not have to be provided.

Furthermore, an acoustic wave device according to the present preferred embodiment may include at least one series resonator and at least one parallel resonator in addition to the longitudinally coupled resonator 20. For example, in the acoustic wave device 103 illustrated in FIG. 7, the first parallel resonator 81 may be connected between the first series resonator 83 and the longitudinally coupled resonator 20, or the second parallel resonator 82 may be connected between the longitudinally coupled resonator 20 and the second series resonator 84. Alternatively, in the acoustic wave device 103 illustrated in FIG. 7, the first parallel resonator 81 and the second parallel resonator 82 that have been described above may further be included. That is, the acoustic wave device 103 according to the present preferred embodiment may include the acoustic wave device 101, the first parallel resonator 81, the second parallel resonator 82, the first series resonator 83, and the second series resonator 84.

As described in the present preferred embodiment, the longitudinally coupled resonator 20 can be combined with various resonators used in a circuit of an acoustic wave device. The parallel resonator and series resonator described above may be other longitudinally coupled resonators or may be capacitance elements other than a resonator.

### Other Preferred Embodiments

Acoustic wave devices according to the present disclosure are not limited to the above-described preferred embodiments, and various modifications can be made. The number of IDT electrodes defining a longitudinally coupled resonator is not limited to six, and the number of IDT electrodes may be four or may be eight or more. Furthermore, for example, the shape of an IDT electrode is not limited to the above-described preferred embodiments.

### Practical Example

As for filter characteristics of an acoustic wave device according to a preferred embodiment of the present invention, results obtained by simulation will be described. As Practical Example 1, filter characteristics of the acoustic wave device 102 according to the second preferred embodiment were obtained by simulation. Parameters of IDT electrodes used in simulation are indicated in the following Table 1. In Table 1, a wavelength of each IDT electrode refers to a value that is twice a main pitch Pm in a main region. Furthermore, the number of electrode fingers refers to the number of electrode fingers in a reflector or IDT. If an IDT electrode includes a main region Rm and a narrow pitch region Rn, a wavelength and the number of electrode fingers are indicated for each region.

TABLE 1

| | | | IDT 22 | | IDT 23 | | |
|---|---|---|---|---|---|---|---|
| | REFLECTOR | | | NARROW | NARROW | | NARROW |
| | 31 | IDT 21 | MAIN | PITCH | PITCH | MAIN | PITCH |
| WAVELENGTH | 4.209 | 4.209 | 3.991 | 3.736 | 3.733 | 4.048 | 3.733 |
| (μm) | | | | | | | |
| NUMBER OF | 17 | 2 | 19 | 6 | 5 | 19 | 5 |
| ELECTRODE | | | | | | | |
| FINGERS | | | | | | | |

| | IDT 24 | | | IDT 25 | | | IDT 26 | | |
|---|---|---|---|---|---|---|---|---|---|
| | NARROW | | NARROW | NARROW | | NARROW | NARROW | | REFLECTOR |
| | PITCH | MAIN | PITCH | PITCH | MAIN | PITCH | PITCH | MAIN | 32 |
| WAVELENGTH | 3.738 | 3.993 | 3.738 | 3.734 | 4.048 | 3.734 | 3.736 | 3.991 | 4.184 |
| (μm) | | | | | | | | | |
| NUMBER OF | 6 | 21 | 6 | 5 | 15 | 5 | 6 | 19 | 15 |
| ELECTRODE | | | | | | | | | |
| FINGERS | | | | | | | | | |

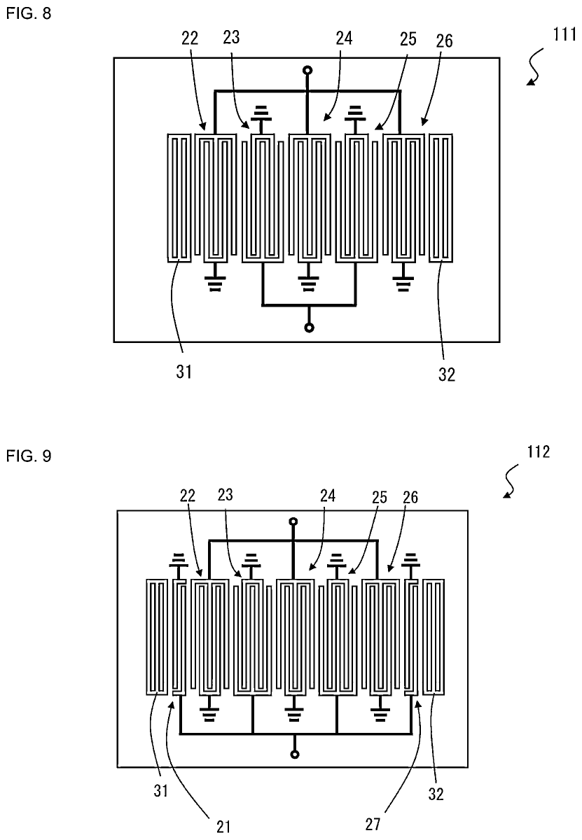

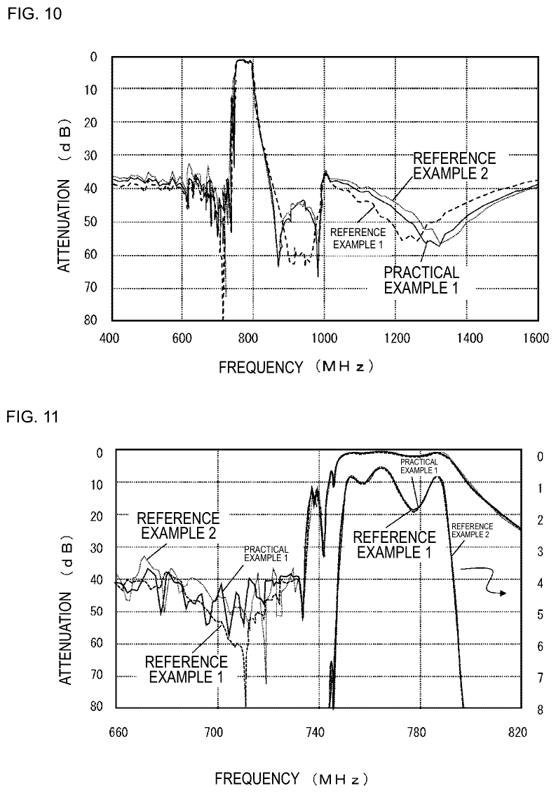

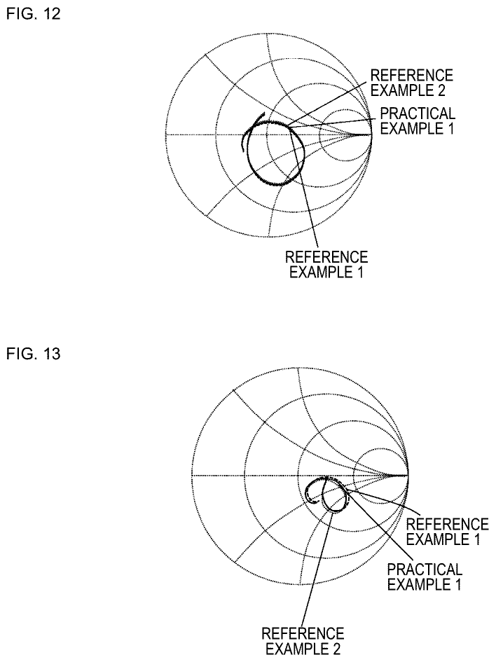

For purposes of comparison, as Reference Example 1, filter characteristics of an acoustic wave device 111 having the same or substantially the same structure as the acoustic wave device 102, except that the acoustic wave device 111 does not include the IDT electrode 21 as illustrated in FIG. 8 were obtained by simulation. Furthermore, as Reference Example 2, filter characteristics of an acoustic wave device 112 further including an IDT 27 having the same or substantially the same structure as the IDT electrode 21 as illustrated in FIG. 9 were obtained by simulation. FIG. 10 illustrates attenuation characteristics in a wide range. Furthermore, FIG. 11 illustrates attenuation characteristics near a pass band. FIGS. 12 and 13 illustrate, as in-band impedance characteristics, respective characteristics of S11 and S22. In FIGS. 10 to 13, a solid line represents characteristics in Practical Example 1, and a rough dotted line represents characteristics in Reference Example 1. Furthermore, a fine dotted line represents characteristics in Reference Example 2.

As illustrated in FIG. 10, it can be seen that, although an attenuation pole in Reference Example 1 is located near about 900 MHz, the corresponding attenuation pole in Practical Example 1 has been shifted to a location of about 870 MHz. As a result, a steep attenuation slope has been achieved at a boundary between the pass band and a stop band on a high frequency side of the pass band. On the other hand, as illustrated in FIG. 11, Reference Example 1 and Practical Example 1 are almost the same in characteristics in the pass band ranging from about 750 MHz to about 800 MHz, and good bandpass characteristics are maintained. Furthermore, as illustrated in FIGS. 12 and 13, Reference Example 1 and Practical Example 1 are almost the same in in-band impedance characteristics as well.

In Reference Example 2, as in Practical Example 1, an attenuation pole has been shifted to the location of about 870 MHz, and a steep attenuation slope has been achieved at the boundary between the pass band and the stop band on the high frequency side of the pass band. Furthermore, Reference Example 1 and Reference Example 2 are almost the same in characteristics in the pass band ranging from about 750 MHz to about 800 MHz. In Reference Example 2, however, in a stop band on a lower frequency side than the pass band, attenuation is small, and attenuation characteristics have deteriorated. Furthermore, as illustrated in FIG. 13, in-band impedance characteristics have been shifted.

From these results, it can be seen that, in Practical Example 1, the IDT including two electrode fingers is added to the longitudinally coupled resonator including an odd number of IDT electrodes to thus enable an improvement in attenuation characteristics at an attenuation pole located outside the band of the band pass filter while maintaining in-band characteristics. Furthermore, it can be seen that it is more preferable that the IDT including two electrode fingers is provided only at one end of the longitudinally coupled resonator.

Next, a preferable range of a pitch of electrode fingers in the IDT electrode 21 was examined by simulation.

The pitch of electrode fingers of the IDT electrode 21 was set to various values, and filter characteristics were obtained by simulation as in Practical Example 1 described above. The obtained results were compared with results obtained in Reference Example 1, and it was determined whether attenuation characteristics at an attenuation pole located outside the band of the band pass filter were able to be improved while maintaining good in-band characteristics.

As a result, it has been discovered that, if the condition of the expression (1) is satisfied, attenuation characteristics at the attenuation pole located outside the band of the band pass filter can be improved while maintaining good in-band characteristics.

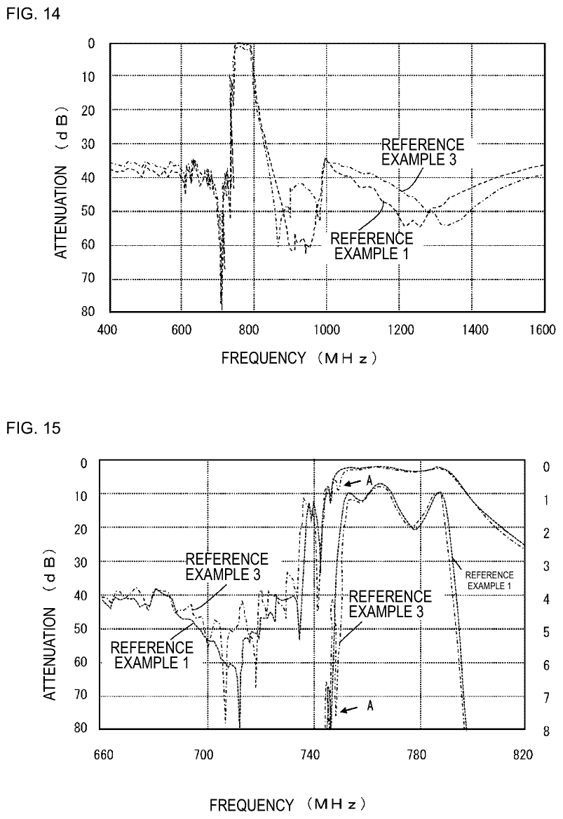

As Reference Example 3, filter characteristics designed based on conditions in the following Table 2 are illustrated in FIGS. 14 and 15. In FIGS. 14 and 15, a rough dotted line represents characteristics in Reference Example 1, and a dashed-dotted line represents characteristics in Reference Example 3. In Table 2, a wavelength of each IDT electrode refers to a value that is twice a main pitch Pm in a main region, and the number of electrode fingers refers to the sum of the number of electrode fingers in the main region and the number of electrode fingers in a narrow pitch region. An average value of wavelengths (that is, P2×2) obtained from pitches of electrode fingers in main regions in the IDTs 22 to 26 was about 4.014 μm.

Furthermore, a wavelength (P1×2) obtained from a pitch of the IDT 21 is about 9.473 μm, and P1=about 2.23×P2 holds true.

TABLE 2

| | | | IDT 22 | | IDT 23 | | |
|---|---|---|---|---|---|---|---|
| | REFLECTOR | | | NARROW | NARROW | | NARROW |
| | 31 | IDT 21 | MAIN | PITCH | PITCH | MAIN | PITCH |
| WAVELENGTH | 4.209 | 9.473 | 3.991 | 3.736 | 3.733 | 4.048 | 3.733 |
| (μm) | | | | | | | |
| NUMBER OF | 17 | 2 | 19 | 6 | 5 | 19 | 5 |
| ELECTRODE | | | | | | | |
| FINGERS | | | | | | | |

| | IDT 24 | | | IDT 25 | | | IDT 26 | | |
|---|---|---|---|---|---|---|---|---|---|
| | NARROW | | NARROW | NARROW | | NARROW | NARROW | | REFLECTOR |
| | PITCH | MAIN | PITCH | PITCH | MAIN | PITCH | PITCH | MAIN | 32 |
| WAVELENGTH | 3.738 | 3.993 | 3.738 | 3.734 | 4.048 | 3.734 | 3.736 | 3.991 | 4.184 |
| (μm) | | | | | | | | | |
| NUMBER OF | 6 | 21 | 6 | 5 | 15 | 5 | 6 | 19 | 15 |
| ELECTRODE | | | | | | | | | |
| FINGERS | | | | | | | | | |

As illustrated in FIG. 14, in Reference Example 3, as in Practical Example 1, a steep attenuation slope has been achieved at the boundary between the pass band and the stop band on the high frequency side of the pass band. As represented by an arrow A in FIG. 15, however, it can be seen that ripple occurred in the pass band and that good passband characteristics have not been maintained.

This is considered to be because the pitch of electrode fingers of the IDT electrode 21 is outside the range of the expression (1) and the pitch is too large. It is considered that good passband characteristics are not able to be maintained even if the pitch of electrode fingers of the IDT electrode 21 is smaller than the range of the expression (1).

Thus, it has been discovered that, when the pitch of electrode fingers of the IDT electrode 21 satisfies the range of the expression (1), attenuation characteristics at the attenuation pole located outside the band of the band pass filter can be improved while maintaining good in-band characteristics.

Acoustic wave devices according to preferred embodiments of the present invention and a methods of manufacturing the acoustic wave devices can also be described as follows.

An acoustic wave device according to a first configuration includes a piezoelectric substrate, and a longitudinally coupled resonator located on a main surface of the piezoelectric substrate and including four or more even number of IDT electrodes. Of the even number of IDT electrodes, of a pair of outermost IDT electrodes, the number of electrode fingers of one IDT electrode is two.

In the first configuration, the acoustic wave device can be obtained that provides a steep attenuation slope at a boundary between a pass band and a stop band and has good bandpass characteristics.

In the acoustic wave device according to a second configuration, the longitudinally coupled resonator may further include a pair of reflectors located on the main surface of the piezoelectric substrate and disposed on outer sides of the even number of IDT electrodes.

In the acoustic wave device according to a third configuration, of the even number of IDT electrodes, the number of electrode fingers of an IDT electrode other than the pair of IDT electrodes may be three or more.

In the acoustic wave device according to a fourth configuration, when a pitch of the electrode fingers of the one IDT electrode is P1 and an average value of main pitches of IDT electrodes other than the one IDT electrode is P2, P1 and P2 may satisfy a relationship of 0.97×P2≤P1≤2.1×P2.

The acoustic wave device according to a fifth configuration may further include a pair of input-output terminals, and at least one resonator connected between a path connecting the longitudinally coupled resonator and one of the pair of input-output terminals and a reference potential.

The acoustic wave device according to a sixth configuration may further include a pair of input-output terminals, and at least one resonator connected in series with a path connecting the longitudinally coupled resonator and one of the pair of input-output terminals.

In the acoustic wave device according to a seventh configuration, the longitudinally coupled resonator may be a band pass filter.

A method of manufacturing an acoustic wave device according to an eighth configuration includes designing filter characteristics of a band pass filter including a longitudinally coupled resonator including three or more odd number of IDT electrodes, modifying the filter characteristics by adding an IDT electrode including two electrode fingers at one end of the odd number of IDT electrodes, and forming a longitudinally coupled resonator on a piezoelectric substrate in accordance with the modified filter characteristics.

In the eighth configuration, an acoustic wave device that provides a steep attenuation slope at a boundary between a pass band and a stop band and has good bandpass characteristics can be designed by using a relatively simple design method and can be manufactured.

In the method of manufacturing an acoustic wave device according to a ninth configuration, in the modifying the filter characteristics, an attenuation pole on a high frequency side outside a pass band of the filter may be modified.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate; and
a longitudinally coupled resonator on a main surface of the piezoelectric substrate and including an even number of four or more IDT electrodes; wherein
of the even number of IDT electrodes, in a pair of outermost IDT electrodes, a number of electrode fingers of one IDT electrode is two.

2. The acoustic wave device according to claim 1, wherein the longitudinally coupled resonator further includes a pair of reflectors on the main surface of the piezoelectric substrate and positioned on outer sides of the even number of IDT electrodes.

3. The acoustic wave device according to claim 1, wherein, of the even number of IDT electrodes, a number of electrode fingers of an IDT electrode other than the one IDT electrode is three or more.

4. The acoustic wave device according to claim 1, wherein, when a pitch of the electrode fingers of the one IDT electrode is P1 and an average value of main pitches of IDT electrodes other than the one IDT electrode is P2, P1 and P2 satisfies a relationship of 0.97×P2≤P1≤2.1× P2.

5. The acoustic wave device according to claim 1, further comprising:
a pair of input-output terminals; and
at least one resonator connected between a path connecting the longitudinally coupled resonator and one of the pair of input-output terminals and a reference potential.

6. The acoustic wave device according to claim 1, further comprising:
a pair of input-output terminals; and
at least one resonator connected in series with a path connecting the longitudinally coupled resonator and one of the pair of input-output terminals.

7. The acoustic wave device according to claim 1, wherein the longitudinally coupled resonator is a band pass filter.

8. The acoustic wave device according to claim 1, wherein the piezoelectric substrate is made of LiTaO₃ or LiNbO₃.

9. The acoustic wave device according to claim 1, wherein the piezoelectric substrate includes a support substrate and a piezoelectric thin film on the support substrate.

10. The acoustic wave device according to claim 1, wherein the piezoelectric substrate is a rotated Y cut LiTaO₃ substrate.

11. The acoustic wave device according to claim 10, wherein the rotated Y cut LiTaO₃ substrate has a rotation angle in a range of not less than about 116° and not more than about 136°.

12. The acoustic wave device according to claim 1, wherein the even number of IDT electrodes is six.

13. The acoustic wave device according to claim 1, wherein the number of electrode fingers of the IDT electrode other than the one IDT electrode is not more than 50.

14. The acoustic wave device according to claim 1, wherein the number of electrode fingers of the IDT electrode other than the one IDT electrode is not less than 20 and not more than 40.

15. The acoustic wave device according to claim 1, wherein each of the IDT electrodes includes Al, Pt, Au, Cu, W, Mo, Ta, Ni, or Cr, or an alloy including at least one of Al, Pt, Au, Cu, W, Mo, Ta, Ni, or Cr.

16. The acoustic wave device according to claim 2, wherein each of the pair of reflectors includes Al, Pt, Au, Cu, W, Mo, Ta, Ni, or Cr, or an alloy including at least one of Al, Pt, Au, Cu, W, Mo, Ta, Ni, or Cr.

17. A method of manufacturing an acoustic wave device, the method comprising:
designing filter characteristics of a band pass filter including a longitudinally coupled resonator including an odd number of three or more IDT electrodes;
modifying the filter characteristics by adding an IDT electrode including two electrode fingers at one end of the odd number of IDT electrodes; and
forming a longitudinally coupled resonator on a piezoelectric substrate in accordance with the modified filter characteristics.

18. The method of manufacturing an acoustic wave device according to claim 17, wherein, in the modifying the filter characteristics, an attenuation pole on a high frequency side outside a pass band of the filter is modified.
